(19) United States
(12) Patent Application Publication
(10) Pub. No.: US 2025/0254910 A1
(43) Pub. Date: Aug. 7, 2025

(54) TRANSISTOR DEVICE AND METHOD OF FORMING A GATE ELECTRODE AND A FIELD PLATE IN A COLUMNAR TRENCH

(71) Applicant: Infineon Technologies Austria AG, Villach (AT)

(72) Inventors: Alessandro Ferrara, Villach (AT); Stefan Tegen, Dresden (DE); David Laforet, Villach (AT)

(21) Appl. No.: 19/045,924

(22) Filed: Feb. 5, 2025

(30) Foreign Application Priority Data
Feb. 6, 2024 (DE) 102024103286.3

(51) Int. Cl. H10D 30/66; H10D 62/10; H10D 64/00; H10D 64/01; H10D 64/27

(52) U.S. Cl. CPC H10D 30/668; H10D 62/124; H10D 64/01; H10D 64/117; H10D 64/513; H10D 64/518

(57) ABSTRACT

In an embodiment, a transistor device is provided that includes a semiconductor substrate having a first major surface, and a columnar trench arranged in the first major surface and having a lower surface and a side wall, the side wall extending from the lower surface to the first major surface. A gate electrode positioned in the columnar trench is electrically insulated from the semiconductor substrate by a gate dielectric. A field plate positioned in the columnar trench under the gate electrode is electrically insulated from the gate electrode and the semiconductor substrate by a field dielectric. The gate electrode is asymmetric about a longitudinal axis of the columnar trench. The field plate includes a field plate extension which extends from the field plate towards the first major surface and laterally adjacent to the gate electrode.

### BACKGROUND

Transistor devices used in power electronic applications are often fabricated with silicon (Si) semiconductor materials. Common transistor devices for power applications include Si CoolMOS®, Si Power MOSFETs and Si Insulated Gate Bipolar Transistors (IGBTs).

A transistor device for power applications may be based on the charge compensation principle and may include an active cell field including a plurality of trenches, each including a field plate for charge compensation. In some designs, the trenches and the mesas that are formed between adjacent trenches each have an elongate striped structure. In some other designs, the trenches and field plates each have a columnar, needle-like shape as, for example, disclosed in DE 10 2014 112371 A1.

Further improvements would be desirable to further improve the performance of transistor devices with columnar field plates, for example by reducing the on-state resistance RDS(on).Area.

### SUMMARY

In an embodiment, a transistor device is provided that comprises a semiconductor substrate comprising a first major surface, a columnar trench arranged in the first major surface and comprising a lower surface and a side wall, the side wall extending from the lower surface to the first major surface. A gate electrode is positioned in the columnar trench and electrically insulated from the semiconductor substrate by a gate dielectric. A field plate is positioned in the columnar trench under the gate electrode and electrically insulated from the gate electrode and from the semiconductor substrate by a field dielectric. The gate electrode is asymmetric about a longitudinal axis of the columnar trench. The field plate comprises a field plate extension which extends from the field plate towards the first major surface and laterally adjacent to the gate electrode.

In an embodiment, a method of forming a gate electrode and a field plate in a columnar trench is provided. The method comprises providing a semiconductor substrate having a first major surface and a columnar trench comprising a lower surface and a side wall that extends from the lower surface to the first major surface, wherein the side wall and the lower surface are lined with a field dielectric and the columnar trench is filled with first conductive material. The method further comprises partially removing the field dielectric, partially removing the first conductive material from the columnar trench and forming a gate recess that is located in the columnar trench asymmetrically with respect to a longitudinal axis of the columnar trench. The method further comprises forming a dielectric material on walls of the gate recess, and inserting second conductive material into the gate recess to form a gate electrode. The first conductive material remaining forms the field plate and extends to the first major surface at a location that is laterally adjacent the gate electrode.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIGS. 1A to 1E illustrate transistor devices according to various embodiments.

FIGS. 2A to 2L illustrate methods of fabricating a gate electrode and a field plate in a columnar trench.

FIGS. 3A to 3K illustrate methods of fabricating a gate electrode and a field plate in a columnar trench.

FIGS. 4A to 4H illustrate top views of metallization structures for transistor devices according to various embodiments.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

In some embodiments, the transistor device is a vertical transistor device, that is has a vertical drift path that extends perpendicularly to two opposing major surface of the semiconductor substrate. The vertical transistor device may be a MOSFET (Metal Oxide Semiconductor Field Effect Transistor) device, an insulated gate bipolar transistor (IGBT) device or a Bipolar Junction Transistor (BJT).

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device but also an emitter of an insulator gate bipolar transistor (IGBT) device and an emitter of a Bipolar Junction Transistor (BJT) device, the term “drain” encompasses not only a drain of a MOSFET device but also a collector of an insulator gate bipolar transistor (IGBT) device and a collector of a BJT device, and the term “gate” encompasses not only a gate of a MOSFET device but also a gate of an insulator gate bipolar transistor (IGBT) device and a base of a BJT device.

The present disclosure provides a transistor design concept for columnar (such as columnar) trench power transistors, e.g. power MOSFETs. In this design concept, it is proposed to integrate the gate and the field-plate in the same columnar trench. This design may be used in combination with a stepped field dielectric, that is a field dielectric that has a greater thickness in a lower portion of the columnar trench than in an upper portion of the columnar trench. This may, for example, enable the pitch of the columnar (columnar) trenches to be reduced in some embodiments.

Reducing the pitch in a conventional columnar trench MOSFET design is challenging as the gate electrode and field plate are arranged in separate trenches, with the gate trench positioned in the mesa formed between the columnar trenches in which the field plates are located. Therefore, the minimum pitch between the columnar trenches is affected by the integration scheme and process variations used to observe a minimal distance between the gate trench and the source mesa contact.

According to the present disclosure, a power transistor device, e.g. a MOSFET, with columnar trenches is provided in which the gate electrode and field plate are located in the same columnar trench. The gate and field plate are electrically isolated from one another, which may reduce the gate to drain charge in some embodiments. The gate and field-plate electrodes within the same trench are separately contacted at the die surface, i.e. at the upper open end of the columnar trench, to gate and source potentials, respectively.

In an embodiment, the power transistor device with columnar trenches having the gate and the field-plate electrode inside the same trench also has a stepped field dielectric in which the field dielectric has a greater thickness on a lower portion of the side wall of the columnar trench than on an upper portion of the side wall of the columnar trench. The field plate has a smaller thickness in the lower portion and a greater thickness in the upper portion of the columnar trench.

A single transistor device may have a plurality of columnar trenches that are arranged in a regular array. Different arrangements of the columnar trenches are possible, such an orthogonal layout and a hexagonal layout. The columnar can have any lateral shape, for example circular, any polygon with a number of sides n that is greater or equal to 3 can be used for the columnar shape. Irregular polygons and elongated shapes are also possible.

The gate and field-plate electrodes are both accessible at the top of the columnar trench and can be reached by their respective contacts. The use of a stepped field-dielectric, e.g. a field oxide, may enable an increased area at the surface of the substrate that is available for forming the contacts to the gate and the field-plate electrodes that are located next to each other. In some embodiments, providing a columnar trench comprising gate and field-plate electrodes inside the same trench may allow pitch shrinkage and a lower RDSonA. In the same or different embodiments, isolating the gate and field-plate electrodes with a dielectric material may reduce a gate-to-drain charge. A lower RdsonA may be provided by the use of a stepped field oxide. A trade-off between Rdson and gate charge Qg can be further tuned by layout, e.g., by modification of the gate and contact masks.

Since the field-plate reaches the top of the columnar trench and is located next to the gate which also reaches the top of the columnar trench, the full circumference of the columnar trench is not available for channel formation. The channel of the transistor device may only be formed next to the gate. Since the gate is not located adjacent to the entire side wall, i.e. does not extend through 360° adjacent the side wall of the trench, due to the field plate contact coming up to the surface of the substrate, the size of the channel is reduced accordingly. In other words, the channel is not formed in the regions along the perimeter of the columnar trench where the field-plate electrode reaches the substrate surface and is located adjacent the perimeter of the columnar trench and adjacent the source and body regions. The percentage of available channel formed at each columnar trench can be tuned by a suitable layout, for example by adjusting the gate mask. The percentage of the columnar trench perimeter which is used to form the channel may lie in the range of 15% to 85% of the total columnar trench perimeter. Increasing the channel percentage improves the Rdson at the expense of the gate charge. Fine tuning of the Rdson-Qg trade-off can be achieved by design of the gate layout. For example, a layout with 50% channel percentage (½ gate) with orthogonal and hexagonal columnar trench arrangement or a layout with 75% channel percentage (¾ gate) with orthogonal and hexagonal columnar trench arrangement may be used.

The integration scheme for the gate and field plate in a single columnar trench is compatible with columnar trench technologies including a polysilicon or a metal gate. The gate/source contact and tungsten line isolation are compatible with columnar trench and BEOL (back end of line) technologies. A potential modulation of the output resistance Ross (to integrate a snubber functionality to reduce oscillations during switching) is provided by varying the thickness of the oxide in the field plate upper portion in combination with the poly resistance. The source contact layout may be optimized for device performance (Ron, Vth, DIBL (drain induced barrier lowering), parasitic turn-on, etc. . . . ). Different contact arrangements and configurations are also possible.

In some designs, the gate charge of the proposed device compared to a columnar trench device with gate grid may show a 50% lower Qgd while having a similar RonA. The device has a better Ron*Qgd figure of merit (FOM) in spite of having a thinner gate oxide, making this concept attractive for fast switching applications where low FOMs are required.

A low voltage columnar trench MOSFET can be provided as a result of the possibility of reducing the pitch between the columnar trenches. The transistor device according to the present disclosure may enable low Rdson and low Qg(d) for low voltage columnar trench MOSFETs, where low voltage denotes breakdown voltage (BV)<=40V. The transistor device according to the present disclosure may also be used in higher voltage classes (BV>=40V), for example for FOM (Figure of Merit) optimized products with low gate charge.

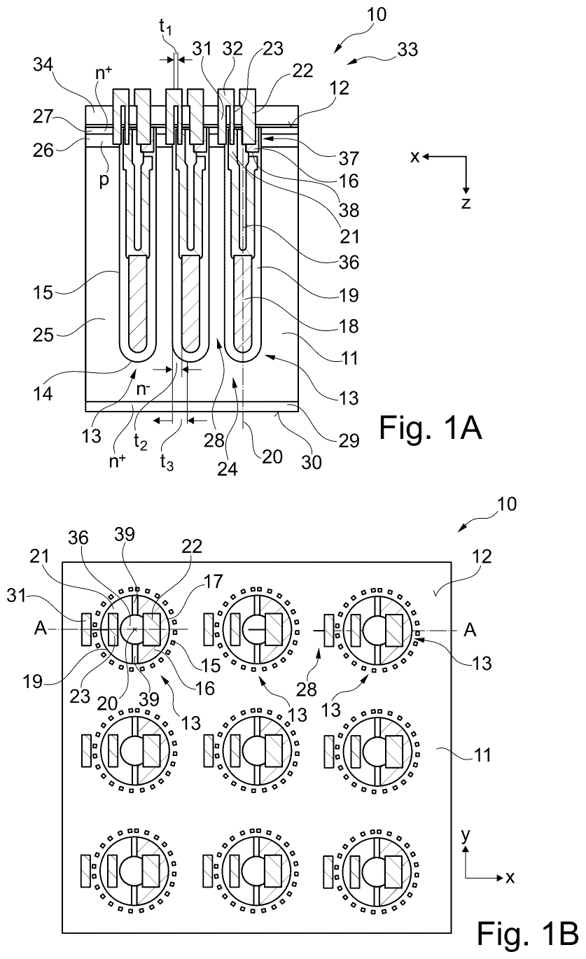

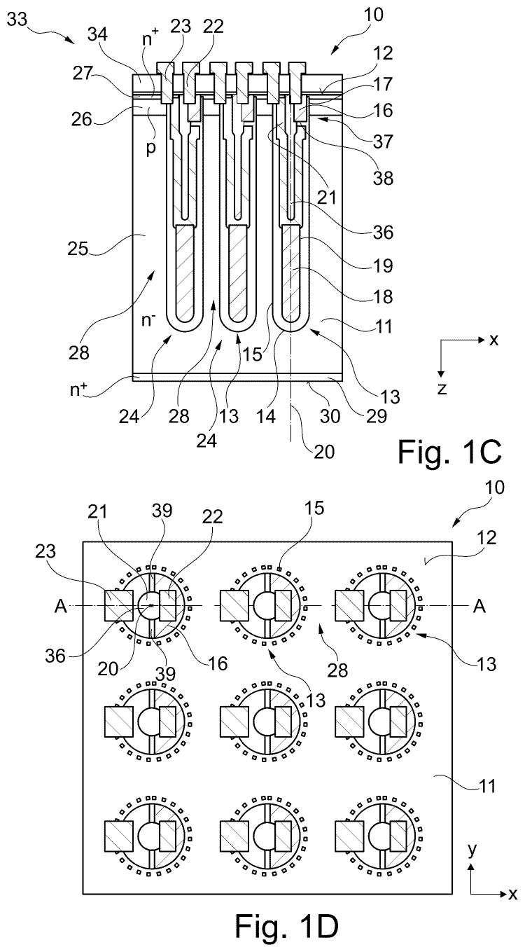

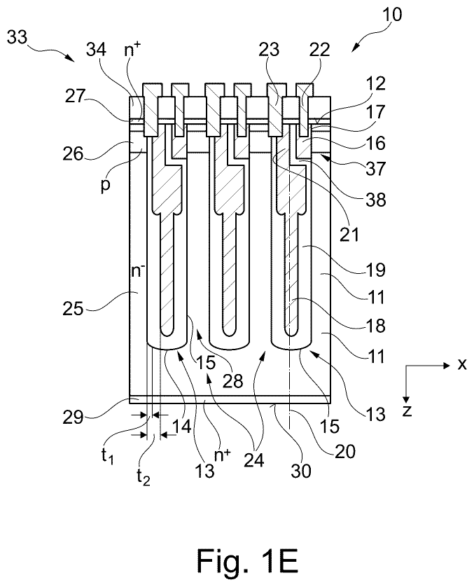

FIGS. 1A to 1E illustrate transistor devices 10 according to various embodiments. FIG. 1A illustrates a cross-sectional view and FIG. 1B a top view of a transistor device 10 according to an embodiment, FIG. 1C illustrates a cross-sectional view and FIG. 1D a top view of a transistor device 10 according to another embodiment, and FIG. 1E illustrates a cross-sectional view of a transistor device 10 according to yet another embodiment.

The transistor device 10 shown in and described with reference to FIGS. 1A to 1E comprises a semiconductor substrate 11 having a first major surface 12 and at least one columnar trench 13 arranged in the first major surface 12. The columnar trench 13 comprises a lower surface 14, which may also be referred to as the bottom, and a sidewall 15 which extends from the lower surface 14 to the first major surface 12.

A columnar trench 13 may also be called a needle-shaped trench and has a small or narrow circumference or width in proportion to its height/depth in the substrate 11 perpendicular to the first major surface 12, as opposed to an elongate striped trench which has a length in a plane parallel to the first major surface 12 that is greater than its depth in the substrate 11. Using the Cartesian coordinate system, the first major surface 12 can be considered to lie in the x-y plane and the height/depth in the z direction.

The columnar (needle) trench 13 may have different shapes in plan view, for example an octagonal, circular, square, hexagonal and shape in plan view. A columnar trench 13 which is circular in plan view has a single continuous side wall 15. A columnar trench 13 which is square in plan view has a side wall 15 with four subsections, adjoining subsections being arranged perpendicularly to one another, a columnar trench 13, which is hexagonal in plan view, has a side wall with six subsections and so on.

The transistor device 10 may comprise a plurality of columnar trenches 13 that may be arranged in a regular array with substantially the same uniform pitch, e g. a square grid array of rows and columns. Alternatively, a plurality of columnar trenches 13 an array of offset rows or a hexagonal array, for example. A mesa 28 is formed by the region of the substrate 11 that laterally surrounds the columnar trench 13, for example that is arranged between adjacent ones of the plurality of columnar trenches 13. Each columnar trench 13 with its gate electrode 16 and field plate 18 may form part of a transistor cell 24 of the transistor device. Typically, the transistor device 10 includes a plurality of transistor cells 24 which are electrically coupled in parallel so as to switch a load.

The transistor device 10 further comprises a gate electrode 16 that is positioned in the columnar trench 13 and that is electrically insulated from the semiconductor substrate 11 by a gate dielectric 17 that is located on the side wall 15 of the columnar trench 13. The transistor device 10 further comprises a field plate 18 which may also be referred to as a field electrode. The field plate 18 is also positioned in the columnar trench 13. The field plate 18 is located in the columnar trench 13 under the gate electrode 16. The field plate 18 is electrically insulated from the gate electrode 16 and from the semiconductor substrate 11 by a field dielectric 19. The gate electrode 16 is asymmetric about a longitudinal axis 20 of the columnar trench 13.

The gate electrode 16 may be asymmetrically located within the columnar trench 13 respect to the longitudinal axis 20 of the columnar trench 13, Asymmetrically located refers to a non-symmetrical location of the gate electrode 16 in the columnar trench 13 with respect to the longitudinal axis 20 of that columnar trench in at least one plane that is parallel to the first major surface 12 and perpendicular to the longitudinal axis 10. In this at least one plane, the remainder of the columnar trench 13 is unoccupied by the gate electrode 16. Since the gate electrode is asymmetrically located within the columnar trench 13 respect to the longitudinal axis 20 of the columnar trench 13, the columnar trench 13 has only one-fold rotational symmetry about the longitudinal axis 20 and no other n-fold rotational symmetry, where n is a natural number. For example, the gate electrode 16 may be located in a single quadrant only of a circular (cylindrical) columnar trench 13. In another example, the gate electrode may be located in two or three adjoining quadrants only of a circular columnar trench 13. The gate electrode 16 is provided by a single electrically conductive member arranged in the columnar trench 13. This single electrically conductive member is located in the columnar trench 13 asymmetrically with respect to the longitudinal axis 20.

The field plate 18 comprises a field plate extension 21 which extends from the field plate 18 located under the gate electrode 16 towards the first major surface 12. The field plate extension 21 extends laterally adjacent to the gate electrode 16, wherein laterally denotes the x-y plane. Thus, the field plate extension 21 and the gate electrode 16 are positioned within a single columnar trench 13 and are located at or under the plane of the first major surface 12. This enables an electrical contact to be made to the gate electrode 16 and the field plate extension 21, which enables electrical connection to the field plate 18 located in the bottom of the columnar trench 13, at the first major surface 13. The first contact 22 and the second contact 23 of a columnar trench 13 are arranged laterally adjacent one another and may be arranged at opposing sides of the columnar trench 13, e.g. on opposing sides of the longitudinal axis 20.

In some embodiments, a first contact 22 to the gate electrode 16 and a second contact 23 to the field plate extension 21 and consequently to the field plate 18, which is located under the gate electrode 16, may be positioned within the area of the columnar trench 13 as defined by the perimeter sidewall 15 at the first major surface 12. The first and second contacts 22, 23 of the columnar trench 13 may be aligned in the x direction.

The semiconductor substrate 11 may be formed of a Group IV semiconductor, such as silicon and may be formed of a monocrystalline epitaxial layer or a single crystal, e.g. a monocrystalline silicon epitaxial layer or a silicon single crystal. The gate electrode 16 and field plate 18 including its field plate extension 21 may comprise electrically conductive material, such as polysilicon. The gate dielectric 17 and field dielectric 19 may be formed of an oxide such as silicon oxide.

The semiconductor substrate 11 may be doped with a first conductivity type, for example n-type and provide the drift region 25 of the transistor device. A body region 26 comprising a second conductivity type which opposes the first conductivity type, e.g. p-type if the first conductivity type is n-type, is formed on the drift region 25 and a source region 27 comprising the first conductivity type is arranged on and/or in the body region 26. A drain region 29 formed of the first conductivity type is formed at the opposing second surface 30 of the semiconductor substrate 11 such that a vertical drift path is formed between the opposing first and second surfaces 12, 30. The source region 27 and drain region 29 are more highly doped than the drift region 25.

In some embodiments, the field plate 18 is electrically connected to source potential. In some embodiments, the columnar trench 13 has a maximum area at in a plane that is parallel to the first major surface 12 and the gate electrode 16 is sized and shaped so as to have a maximum area a_{g} in the plane that is parallel to the first major surface and such that 10%≤(a_{g}/aₜ)*100≤90% or 20%≤(a_{g}/aₜ)*100≤80%, 25%≤(a_{g}/aₜ)*100≤75%. In some embodiments, the field plate extension is sized and shaped so as to have a maximum area aₑ in the plane that is parallel to the first major surface and such that 10%≤(aₑ/aₜ)*100≤90% or 20%≤(aₑ/aₜ)*100≤80%, 25%≤(aₑ/aₜ)*100≤75%. In some embodiments, a ratio of aₑ/a_{g} lies within the range of 1/9 to 9/1.

In some embodiments, the columnar trench 13 has a circumference (perimeter) Aₜ in a plane that is parallel to the first major surface 12 and the gate electrode 16 is sized and shaped so as to have a maximum circumferential length (perimeter length) A_{g} in the plane that is parallel to the first major surface and such that 10%≤(A_{g}/Aₜ)*100≤90% or 20%≤(A_{g}/Aₜ)*100≤80%, 25%≤(A_{g}/Aₜ)*100≤75%. In some embodiments, the field plate extension is sized and shaped so as to have a maximum circumferential length Aₑ in the plane that is parallel to the first major surface and such that 10%≤(Aₑ/Aₜ)*100≤90% or 20%≤(Aₑ/Aₜ)*100≤80%, 25%≤(Aₑ/Aₜ)*100≤75%. In some embodiments, a ratio of Aₑ/A_{g} lies within the range of 1/9 to 9/1.

By arranging the gate electrode 16 in the same trench as the field plate 18, space within the mesa 28 is not occupied by a separate trench for the gate electrode. This enables the pitch of the array of columnar trenches 13, that is the centre-to-centre pitch, and the width of the mesa 28 to be reduced, which may reduce RDS(on).Area.

The gate electrode 16 and the field plate 18 including its field plate extension 21 that are located in a columnar trench 13 may be electrically insulated from one another using various arrangements of electrically insulating material and/or dielectric material, which together provide the field dielectric.

FIG. 1A illustrates a cross-sectional view along the line A-A shown in FIG. 1B.

In some embodiments, the field dielectric 19 on the side wall 15 of the columnar trench has two or more different thicknesses. Referring to FIGS. 1A and 1B, the field dielectric 19 has a first thickness t₁ at a first distance from the lower surface 14 that is smaller than a second thickness t₂ of the field dielectric 19 at a second distance from the lower surface 14 and a third thickness t₃ at a third distance from the lower surface 14, wherein the first distance is greater than the second distance that is in turn greater than the third distance. A first perimeter of the columnar field plate 18 at the first distance is greater than a second perimeter of the columnar field plate 18 at the second distance and the second perimeter is greater than a third perimeter of the field plate 18 at the third distance. The first distance may be in a plane that dissects the field plate extension 21.

In some embodiments, the side face of the field plate 18 comprises a step such that an upper portion of the field plate has a width that is greater than a width of a lower portion of the field plate and such that the field dielectric 19 has the second thickness t₂ in a first region of the side wall 15 of the columnar trench 13 and a third thickness t₃ in a second region of the side wall of the columnar trench, wherein t₂≤1.15 t₃ or t₂≤1.2 t₃ or t1≤1.5 t₃. In some embodiments, t₁>2. In some embodiments, t₂>t₃. The difference between t₂ and t₃ is greater than that arising from processing variations.

In some embodiments, the side face of the field plate 18 comprises a step at the transition to the field plate extension 21 such that the field dielectric 19 has a first thickness t₁ in a first region of the side wall 15 of the columnar trench 13 that borders the field plate extension 21 and the second thickness t2 in the second region of the side wall 15 of the columnar trench 13 that borders the upper portion of the field plate 18, wherein t₁≤1.15 t₂ or t₁≤1.2 t₂ or t1≤1.5 t₂.

Referring to FIGS. 1A and 1B, in some embodiments, an intermediate electrically insulating layer 36 is arranged centrally along the longitudinal axis 20 of the columnar trench 13. For example, the intermediate electrically insulating layer 36 may be cylindrical if the columnar trench 13 is substantially cylindrical, i.e. is circular in plan view. The intermediate electrically insulating layer 36 extends vertically from the first major surface 12 into the trench 13 along the longitudinal axis 20 and is located centrally within the columnar trench 13 and extends into the columnar trench 13 from the first major surface 12 by a distance which is greater than the height of the gate electrode 16, i.e. greater than the distance of the base (lower surface) of the gate electrode 16 from the first major surface 12. The intermediate electrically insulating layer 36 has a rod-like shape and is located between an inner side wall of the gate electrode 16 and the field plate extension 21 which is positioned laterally adjacent the gate electrode 16.

The gate electrode 16 is located in a gate recess 37 which is located in the columnar trench 13 adjacent a section of the sidewall 15 and between the sidewall 15 and the intermediate electrically insulating layer 36. The intermediate electrically insulating layer 36 extends from the first major surface 12 beyond the base of the gate electrode 16 and the bottom of the gate recess 37 so that the upper region of the field plate 18 that is arranged under the gate recess 37 has a ring-shape. The lower region of the field plate 18 is located under the intermediate electrically insulating layer 36 and the ring-shaped upper portion fills the remaining area of the columnar trench 13 that is unoccupied by the field dielectric 19 on the side wall 15 and lower surface 14 of the columnar trench 13.

The gate recess 37 is located in the columnar trench 37 asymmetrically with respect to the longitudinal axis 20. The gate recess 37 is bounded on its outer sidewall by the gate dielectric 17 arranged on the upper portion of the side wall 15 of the columnar trench 13, at its inner sidewall by the central intermediate electrically insulating layer 36, at its lower surface by a lateral electrically insulating layer 38 and at its two further sidewalls by a vertical electrically insulating layer 39. The gate recess 37 is, therefore, electrically separated from the field plate 18 located under the gate recess 37 by the lateral electrically insulating layer 38 and from the field plate extension 21, which is located laterally adjacent the inner sidewall of the gate recess 37, by the central intermediate electrically insulating layer 36 and the vertical electrically insulating layers 39. The gate electrode 16 is therefore electrically separated from the semiconductor substrate 11 by the gate dielectric 17 and from the field plate 18 and field plate extension 21 by the intermediate electrically insulating layer 36 and the additional electrically insulating layers 38, 39.

In some embodiments, the gate recess 37 and consequently the gate electrode 16 has the form of an arc. An arc can also be described as an open ring-shape with a gap located between two distal ends of the open ring-shape. The field plate extension 21 is located in the gap of the gate electrode 16. The second contact 23 to the field plate 18 is also located in this gap and is positioned laterally adjacent and separate from the gate electrode 16 in the columnar trench 13. The field plate extension 21 may also have an arc or open-ring shape.

In some embodiments, the field plate 18 is electrically connected to source potential. This electrical connection may be provided by various arrangements.

The area of the second contact 23 may be less than the area of the gate electrode 16. The first contact 22 may be in direct physical contact with the gate electrode 16 so that the base (lower surface) of the first contact 22 is positioned below the first major surface 12. The area of the second contact 23 may be smaller than the area of the field plate extension 21 at the first major surface 12. The second contact 23 may also extend into and be in physical contact with the field plate extension 21 and have a base (lower surface) that is positioned below the first major surface 12.

In some embodiments, such as that illustrated in FIGS. 1A and 1B, the transistor device 10 comprises a third contact 31 for each of the columnar trenches 13 which extends into the source region 27 and body region 26 located in the mesa 28 formed between adjacent ones of the columnar trenches 13. The third contact 31 may be arranged laterally adjacent to the second contact 23 to the field plate 18, for example be aligned in the x direction. The third contact 31 may be electrically connected to the second contact 23 in order to electrically connect the field plate 18 to source potential. In some embodiments, the third contact 31 may be electrically connected to the second contact 23 by a conductive trace 32 that is arranged on the first major surface 12 of the semiconductor substrate 11.

As shown in FIG. 1A, the transistor device 10 may comprise a metallisation layer 33 on the first major surface which comprises one or more dielectric layers 34 which are positioned directly on the first major surface 12 and through which the contacts 22, 23, 31 extend. The metallisation layer 33 may comprise a first electrically conductive redistribution structure 34 which extends between and electrically connects the first contacts 22, one of which is located in each of the columnar trenches 13 of the regular array, and gate electrodes 16 to one another and the second electrically conductive structure 32 which electrically connects the second contacts 23 and the third contacts 31 to one another and consequently the field plates 18 to the source region 27 and source potential.

The first contact 22 and second contact 23 associated with a particular columnar trench 13 may be arranged on opposing sides of the columnar trench 13, for example on opposing sides of the longitudinal axis 20, as shown in the top view of FIG. 1B. This reflects the asymmetric location of the gate electrode 16 within the area of the columnar trench 13. In this embodiment, the gate electrode 16 and the field plate extension 21 have an open-ring shape that have distal ends. The gate electrode 16 and the field plate extension 21 can be considered to have an arc section of a cylindrical shape. The vertical electrically insulating layer 39 is arranged between the respective distal ends of the open-ring-shapes of the gate electrode 16 and the field plate 18 in order to electrically insulate the gate electrode 16 and the field plate 18 from one another. The gate electrode 16 and the field plate 18 each have an outer perimeter having a length that is slightly less than half the perimeter or inner circumference of the side wall 15 of the columnar trench 13. The open-ring-shape of the gate electrode 16 and field plate extension 21 together laterally surround the intermediate electrically insulating layer 36 which has the form of a substantially cylindrical member. In some embodiments, the second contact 23 to the field plate 18 and/or the first contact 22 to the gate electrode 16 is also in physical contact with the intermediate electrically insulating layer 36.

The field plate 18 is located under the gate electrode 16 and is connected to the field plate extension 21. The upper portion of the field plate 18 comprises a ring-shaped structure and is located between the central intermediate electrically insulating layer 36 and the field dielectric 19 which is positioned on the sidewall 15 of the columnar trench 13. The lower portion of the field plate 18 is located under the intermediate electrically insulating layer 36 and fills the region of the columnar trench 13 bounded by the field dielectric 19 which lines the lower surface 14 and sidewall 15 of the columnar trench 13. The lower portion of the field plate 18 may have a cylindrical form, for example if the columnar trench has a substantially cylindrical form. The lateral electrically insulating intermediate layer 38 may also be arranged between the lower surface of the gate electrode 16 and the field plate 18.

Since the field plate extension 21 reaches the top of the columnar trench 13 and is located next to the gate electrode 16 which also reaches the top of the columnar trench 13, the channel of the transistor device 10 is not formed in the regions along the perimeter of the columnar trench 12 where the field plate 18 reaches the first major surface 12. The percentage of the trench perimeter which is used to form the channel may lie in the range of 15% to 85% of the total columnar trench perimeter. Increasing the channel percentage improves the Rdson at the expense of the gate charge. Fine tuning of the Rdson-Qg trade-off can be achieved by design of the gate electrode 16. For example, a layout with 50% channel percentage (½ gate) with orthogonal and hexagonal columnar trench arrangement or a layout with 75% channel percentage (¾ gate) may be used.

FIGS. 1C and 1D illustrate a cross-sectional view along the line A-A shown in FIG. 1D and a top view, respectively, of a transistor device 10 according to another embodiment. The transistor device of FIGS. 1C and 1D differs that illustrated in FIGS. 1A and 1B in that the second contact 23 is sized and shaped and located so as to be in direct contact with the field plate extension 21 and with the body region 26 and source region 27 formed in the mesa 28. The second contact 23 can be considered to extend through the sidewall 15 of the columnar trench 13 such that its base (lower surface) is positioned in the field plate extension 21 on the field dielectric 19 and also in contact with the body region 26. Therefore, the single contact 22 electrically connects the field plate extension 21 and the field plate 18 with the body region 26 and the source region 27 and thus electrically couples the field plate 18 to source potential.

In the transistor device 10 of the embodiment illustrated in FIGS. 1A and 1B, the electrical connection of the field plate 18 to source potential is provided by way of the second metallisation structure 32 which is positioned on the dielectric layer 34 located on the first major surface 12 and which extends between the separate second and third contacts 23, 31. The second metallisation structure 32 may be formed from the same deposited layer as the contacts 23, 31 by patterning a portion of the deposited layer that is located on the dielectric layer 34 to form a conductive trace. The transistor device 10 of the embodiment illustrated in FIGS. 1C and 1D differs from the embodiment illustrated in FIGS. 1A and 1B in that the single second contact 23 electrically connects the field plate 18 with the source region and is in direct contact with both the source region 27 and the field plate 18. The further features of the transistor device 10 of the embodiment illustrated in FIGS. 1C and 1D may be the same as those of the transistor device illustrated in FIGS. 1A and 1B.

FIG. 1E illustrates a transistor device 10 according to an embodiment which differs from that illustrated in FIGS. 1A to 1D in the size, shape and location of the intermediate electrically insulating layer 36 which is located between the field plate extension 21 and the gate electrode 16 in the upper portion of the trench columnar trench 13. The further features of the transistor device 10 of the embodiment illustrated in FIG. 1E may be the same as those of the transistor device illustrated in FIGS. 1A and 1B.

In the transistor device 10 of the embodiment illustrated in FIG. 1E, the intermediate electrically insulating layer 36 extends into the columnar trench 13 from the first major surface 12 by a distance such that its end is positioned between the lower surface of the gate electrode 16 and the field plate 18 and is aligned with the lateral electrically insulating layer 38 on the lower surface of the gate recess 37. The intermediate electrically insulating layer 36 forms the inner side face of the gate recess 37 for the gate electrode 16 but in contrast to the embodiments shown in FIGS. 1A to 1D does not extend further into the conductive material of the field plate 18 and beyond the lateral electrically insulating layer 38 on the bottom of the gate recess 37. The field plate 18 that is arranged under the gate electrode 16 fills the entire area of the columnar trench 13 that is unoccupied by the field dielectric 19. The intermediate electrically insulating layer 36 may be asymmetrically arranged with respect to the longitudinal axis 20 of the columnar trench 13, for example laterally offset from the longitudinal axis 20 towards the gate electrode 16. The intermediate electrically insulating layer 36 may also form the further two side faces of the gate recess 37 so that the gate electrode 16 within the gate recess 37 is electrically insulated from the field plate 18 and its field plate extension 21 that is also located in the columnar trench 13.

In some embodiments, the field plate extension 21 may extend along the longitudinal axis 20 and the gate recess 37 is laterally offset from the longitudinal axis 20. The bottom of the gate recess 37 is formed by the lateral electrically insulating layer 38. The field plate 18 fills the region of the columnar trench 13 beneath the lateral electrically insulting layer 38 and beneath gate electrode 16 which is not occupied by the field dielectric 19.

In the transistor device 10 of FIG. 1E, the field dielectric 19 has two different thicknesses on the side wall 15 of the columnar trench 13. A first thickness t₁ of the field dielectric 19 at a first distance from the lower surface 14 is smaller than a second thickness t₂ of the field dielectric at a second distance from the lower surface 14, wherein the first distance is greater than the second distance. The side face of the field plate 18 comprises a step such that the field dielectric 19 has a first thickness t₁ in a first region of the side wall 15 of the columnar trench 13 that adjoins the field plate extension 21 and is laterally adjacent to the gate electrode 16 and a second thickness t2 in a second region of the side wall 15 of the columnar trench 13 that adjoins the field plate 18 under the gate electrode 16, wherein t₁≤1.15 t₂ or t₁≤1.2 t₂ or t1≤1.5 t₂. In some embodiments, t₁>t₂. In some embodiments, t₂>t₃. The difference between t₁ and t₂ is greater than that arising from processing variations.

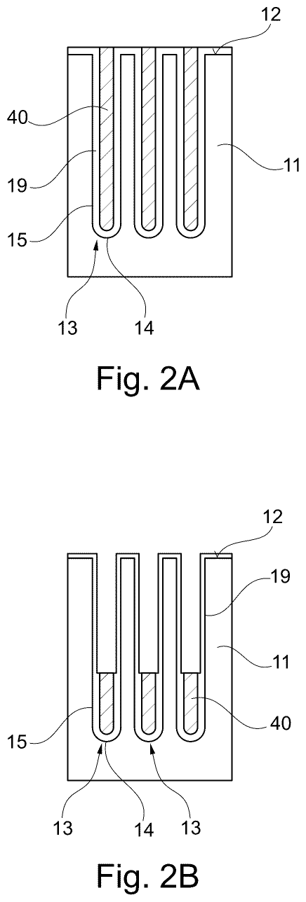

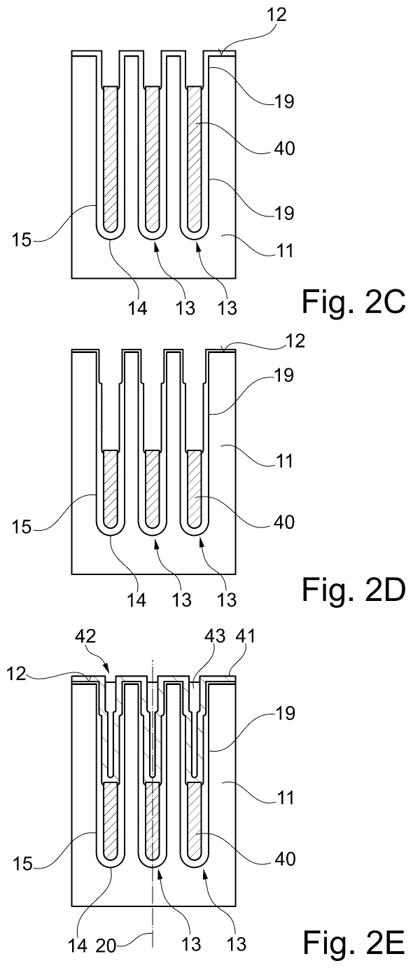

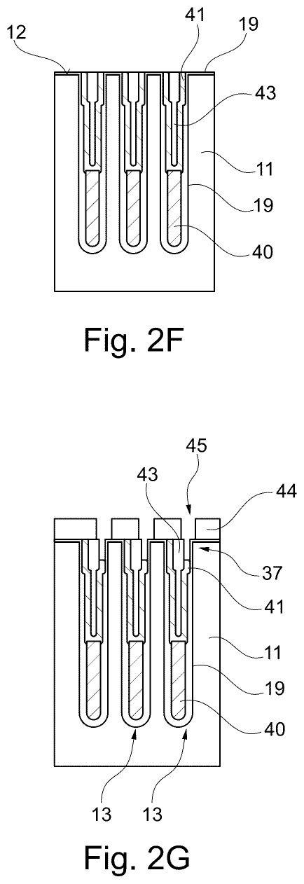

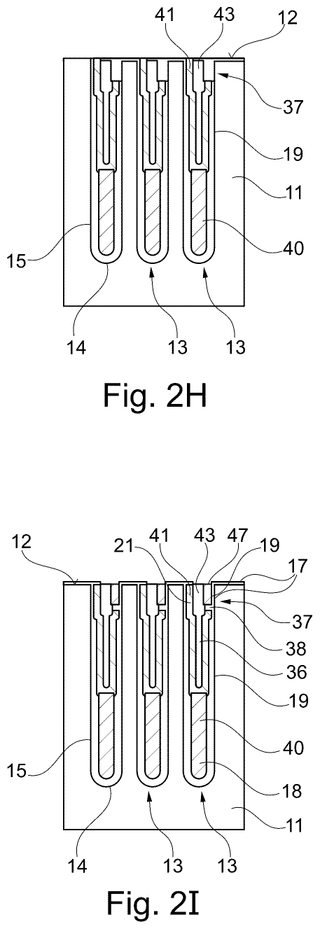

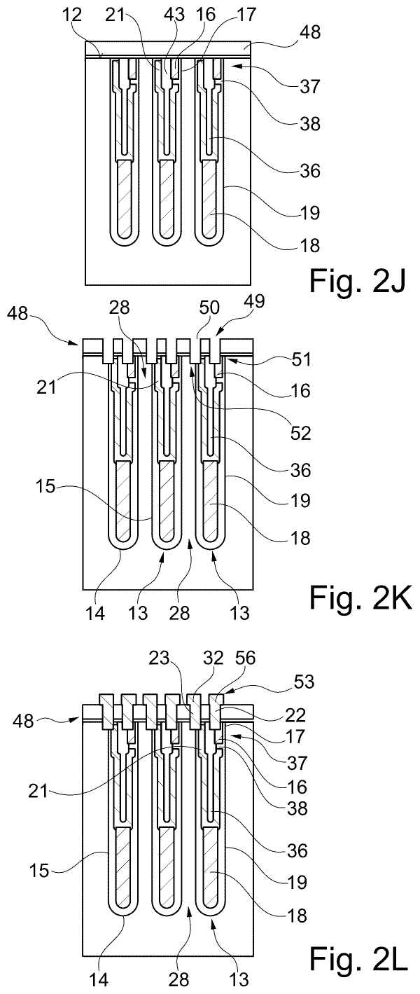

Methods of fabricating a gate electrode and a field plate in a columnar trench will now be described with reference to FIGS. 2A to 2L. The methods described with reference to FIGS. 2A to 2L may be used to fabricate the columnar trench 13 and the transistor device 10 illustrated in FIGS. 1A to 1D.

Referring to FIG. 2A, a semiconductor substrate 11 having a first major surface 12 and at least one columnar trench 13 is provided. The semiconductor substrate 11 may include a plurality of columnar trenches 13, which are arranged in a regular array, for example a square grid array or offset rows which each have substantially the same structure. The plurality of columnar trenches 13 may be processed using the same process steps. The columnar trench 13 has a lower surface 14, which may also be called the bottom of the trench, and a sidewall 15 which extends from the lower surface 14 to the first major surface 12. The sidewall 15 and the lower surface 14 are lined with a field dielectric 19 and the remainder of the columnar trench 13, i.e. the central region, which is bounded by the field dielectric 19, is filled with a first conductive material 40.

The semiconductor substrate 11 may be formed of silicon, for example a monocrystalline epitaxial silicon layer or a silicon single crystal. The body region 25 and source region 27 may have already been formed, for example by implantation of suitable dopants into the first major surface 12. The first conductive material 40 may be selected so as to be suitable for forming a field plate. For example, the first conductive material 40 may be polysilicon. The field dielectric 19 may be formed of an oxide, for example silicon oxide. The dielectric material 19 may also extend over the first major surface 12.

In one embodiment, the method continues as described with reference to FIG. 2B. In an alternative embodiment, the method continues as described with reference to FIGS. 2C and 2D.

Referring to FIG. 2B, a portion of the first conductive material 40 is removed from the upper portion of the columnar trench 13 exposing the field dielectric 19 on the upper portion of the sidewall 15 of the columnar trench 13. The first conductive material 40 may be preferentially removed over the material of the field dielectric 19, for example by selective etching, e.g. wet etching. The selectivity of the conductive material 40 over the material of the field dielectric 19 to the etch may be around 100 to 1 (it could also be less, such as 50 to 1 in some examples). In some embodiments, a portion, e.g. surface, of the exposed field dielectric 19 is also removed in this process (in other embodiments, this may be done in a separate process), thus reducing the thickness of the field dielectric 19 in the upper portion of the columnar trench 13 and also on the first major surface 12. The first major surface 12 and the upper portion of the side wall 15 of the columnar trench 13 remains covered with a thinner layer of the field dielectric 19. The field dielectric 19 then has two differing thicknesses on the sidewall 15, a first larger thickness in the lower section which is in contact with the remainder of the first conductive material 40 and a second smaller thickness in the upper section which is exposed from the conductive material 40. The method may continue as described with reference to FIGS. 2E to 2L.

Referring to FIG. 2C, in the alternative embodiment, the first conductive material 40 within the trench columnar trench 13 is removed, e.g. preferentially removed over the material of the field dielectric 19, for example by selective etching, e.g. wet etching, from an uppermost portion of the columnar trench 30 to a smaller depth than the embodiment illustrated in FIG. 2B. The field dielectric 19 is also exposed over a smaller depth in the upper and intermediate portion of the side wall 15 of the columnar trench 13. The thickness of the exposed region of the field dielectric 19 may also be reduced slightly by this process.

Referring to FIG. 2D, a further removal process is carried out so as to remove a further section of the first conductive material 40 and a portion of the field oxide 19 which is positioned on the sidewall 15 in the uppermost portion of the columnar trench 13 and on the side wall 15 in the intermediate section of the columnar trench 13. In this embodiment, the field dielectric 19 comprises three differing thicknesses on the sidewall 15 of the trench. The thickness is greatest in the lower portion of the trench in which the field dielectric 19 is in contact with the remainder of the first conductive material 40. The field dielectric 19 has second thickness which is slightly less than the first thickness in the intermediate portion which is uncovered during the second etching process and has a third thickness, which is less than the second thickness, in the uppermost portion of the trench 13, which is partially removed in both removal, e.g. etching, processes. This arrangement is in contrast with the embodiment shown in FIG. 2B in which the field dielectric has only two differing thicknesses on the sidewall 15. The alternative method then continues as described with reference to FIGS. 2E to 2L.

Referring to FIG. 2E, a second conductive material 41 is deposited which extends over exposed field dielectric 19 on the first major surface 12 and on the sidewall 15 of the columnar trench 13. The second conductive material 41 may also cover the exposed upper surface of the first conductive material 40. The second conductive material 41 forms a conductive layer which surrounds a gap 42 which is located centrally in the columnar trench 13 and which extends along the longitudinal axis 20 of the columnar trench 13. The first and second electrically conductive materials 40, 41 may have the same or a similar composition, for example polysilicon. This gap 42 is then filled with an electrically insulating material 43 for example silicon oxide, and forms a central intermediate electrically insulating layer 36.

Referring to FIG. 2F, a planarisation process may be carried out to remove the second conductive material 41 form the first major surface 12 and to expose the remainder of the field dielectric layer 19 arranged on the first major surface 12. The method continues by forming the gate recess 37 and gate electrode 16 in the upper portion of the columnar trench 13.

Referring to FIG. 2G, a mask 44 is formed on the first major surface 12 which includes openings 45 which are sized, shaped and arranged for forming a gate recess 37. The openings 45 which are sized, shaped and arranged so as to expose a region of the central electrically insulating material 43 and a region of the second conductive material 25 which is located laterally asymmetrically with respect to the longitudinal axis 20 of the columnar trench 13 and within the columnar trench 13. For example, the opening 45 in the mask 44 may have an arc shape which may also be described as an open ring-shape having a gap between two distal ends of the open ring-shape. The remainder of the second conductive material 41 within the columnar trench 13 and, optionally, also a region of the electrically insulating layer material 43 is covered by the mask 44. The exposed region of the second conductive layer 41 is removed to form a single gate recess 37 located in a section of the area of the columnar trench 13. The intermediate electrically insulating layer 36 in combination with the mask 44 acts as an etch stop and assists in at least partially self-aligning the location of the gate recess 37 within the columnar trench 13. The gate recess 37 is lined on its outer side face by the field dielectric 19 located on the sidewall 15 of the trench 13 and on its inner side face by the exposed portion of the intermediate electrically insulating layer 36. At this stage of the method, the lower surface of the gate recess 37 and the two further sidewall sections are formed by the exposed second conductive material 41.

Referring to FIG. 2H, the mask 44 is removed. The exposed region of the field dielectric 19 is removed and the upper section of the side wall 15 of the columnar trench 13 and the first major surface 12 is exposed. Referring to FIG. 2I, a further electrically insulating layer 17 is deposited or grown, for example, by thermal oxidation, which covers the lower surface and sidewall sections of the gate recess 37 such that the gate recess 37 is lined with electrically insulating and/or dielectric material. The thickness of the electrically insulating layer 17 on the side wall 15 of the columnar trench 13 is suitable for providing the gate dielectric 17 of the transistor device 10. The thickness of the electrically insulating layer 17 may be higher on the lower surface and other side wall sections of the gate recess 37. If the gate dielectric is deposited, then the thickness of the gate dielectric on the lower surface and side walls, i.e. the sections 17, 38 and 39 may be the same. If the gate dielectric is thermally grown, the regions on the lower surface and side wall formed by polysilicon, i.e. the sections 38, 39, may have a thickness that is greater than the section 17 formed on the side wall formed from silicon. For example, for thermally grown silicon oxide, the thickness of the thermally grown gate dielectric may be 2 to 3 times greater in the sections 38, 39 than in the section 17 because silicon oxide grows faster on polysilicon than silicon. Electrically conductive material 47, e.g. polysilicon, is then inserted into the gate recess 37 to form the gate electrode 16 which is electrically insulated by the electrically insulating material 17 from the second conductive material 41 in the columnar trench 13, which forms the field plate 18 and field plate extension 21, and from the semiconductor substrate 11.

Referring to FIG. 2J, the method may continue by depositing one or more dielectric layers 48 on the first major surface 12 which cover the columnar trenches 13 and the gate electrode 16 and field plate extension 21. Referring to FIG. 2K, for at least one of the columnar trenches 13, a first opening 49 may be formed in the dielectric layers 48 which exposes the gate electrode 16 and a second opening 50 may be formed which exposes the second conductive material 41 in a position that is laterally adjacent the gate electrode 16. In some embodiments, the second opening 50 also exposes a region of the mesa 28 formed contiguous to the sidewall 15 of the columnar trench 13. An etch process may then be carried out to remove a portion of the material of the gate electrode 16 and the second conductive material 41 and, if exposed, a contiguous portion of the mesa 28 to form first and second contact openings 51, 52. This etch process may also be used to form third openings for the contacts 31 to the mesas 31.

Referring to FIG. 2L, electrically conductive material 53 may then be inserted into the first and second openings 51, 52 to form a first contact 22 to the gate electrode and a second contact 23 to the second conductive material 41. The second electrically conductive material 41 forms the field plate extension 21 and is electrically connected to the first conductive material 40 in the lower portion of the columnar trench 13 that forms field plate 18 within the lower portion of the columnar trench 13. In a plane that is not shown in FIG. 2L, the electrically conductive material 53 is also inserted into third openings to form the contacts 31 to the mesas 28. The electrically conductive material 53 may be polysilicon or a metal and may include two or more sublayers of differing composition, e.g. different metals or alloys.

In some embodiments, a first lateral redistribution structure 56 may be formed which extends between the first contacts 22 and electrically connects the gate electrodes 16 within different columnar trenches 13 to one another. A second lateral redistribution structure 32 may be formed which extends between the second contacts 23 to another and electrically connects the field plates 18 and body and source regions 26, 27 to one another.

The first and second lateral redistribution structures 56, 32 may be formed at the same time as the electrically conductive material 53 is inserted into the first and second openings 51, 52 and into the third openings for the mesa contacts 31. The electrically conductive material is further formed on the first major surface and is then patterned to form separate lateral redistribution structures 56, 32. The lateral redistribution structure 56 is used to electrically connect the first contacts 22 and gate electrodes 16 to one another. The second lateral redistribution structure 32 is used to electrically connect the second contacts 23 and the field plates 18 and the contacts 31 to the mesas 28 to one another.

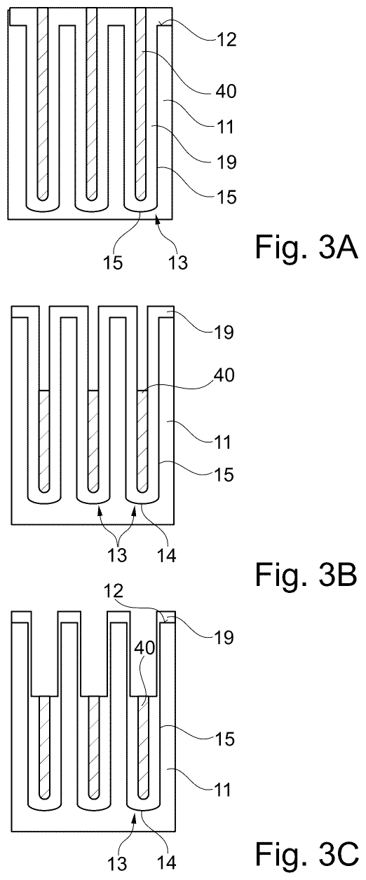

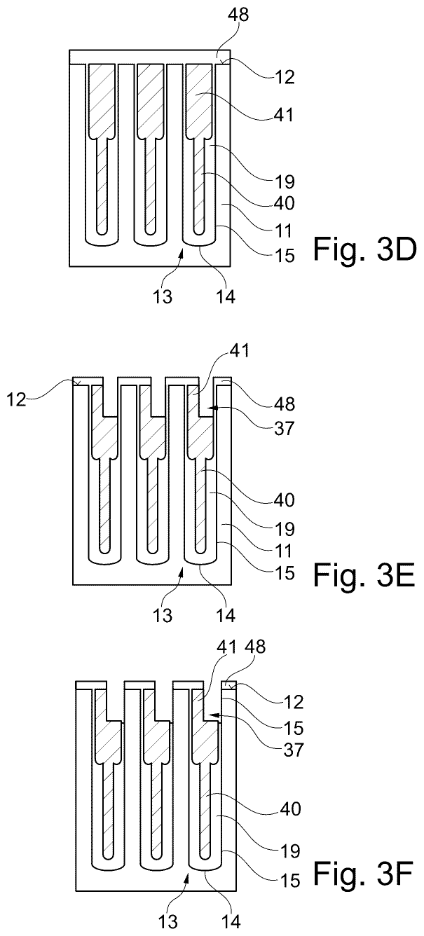

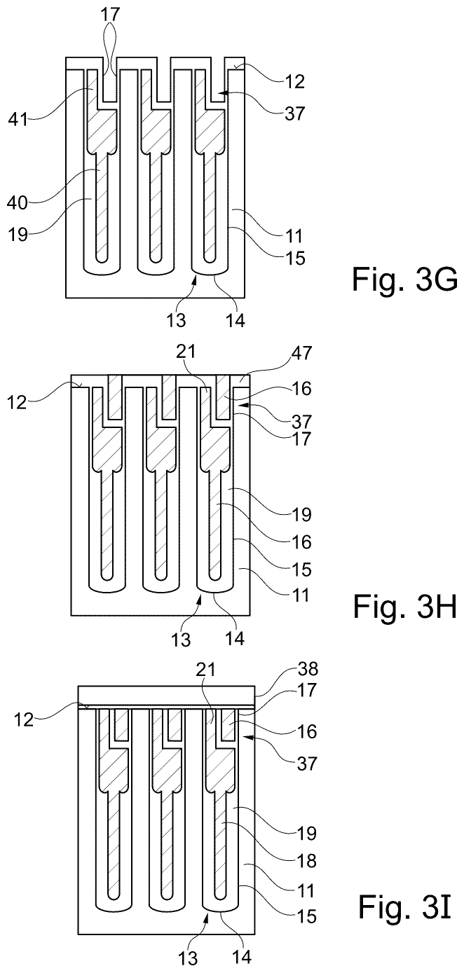

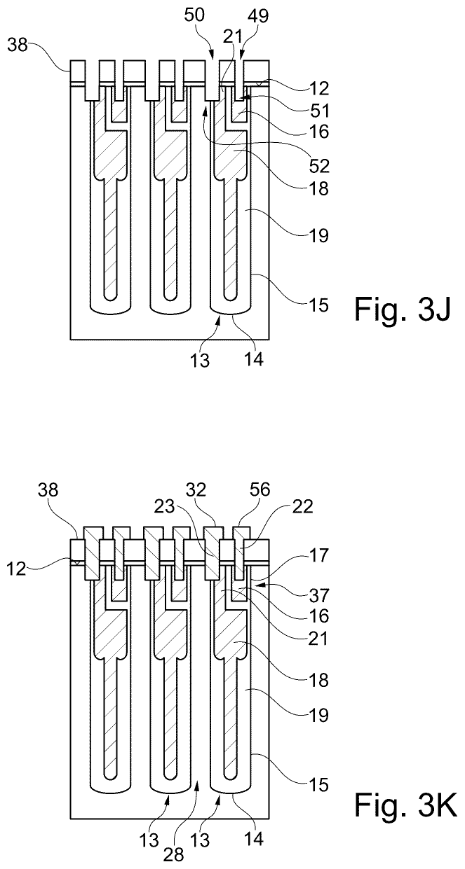

A method for forming a gate electrode and field plate in a columnar trench according to another embodiment will now be described with reference to FIGS. 3A to 3K. The method described with reference to FIGS. 3A to 3K may be used to fabricate the columnar trench 13 and transistor device 10 illustrated in FIG. 1E.

Referring to FIG. 3A, a semiconductor substrate 11 having a first major surface 12 and a least one columnar trench 13 is provided as described with reference to FIG. 2A. Each of the columnar trenches 13 has a lower surface 14 and sidewall 15 extending from the lower surface 14 to the first major surface 12. The first major surface 12, sidewall 15 and lower surface 14 of the columnar trenches 13 are covered with an electrically dielectric layer 19 which surrounds a gap in the centre of each of the columnar trenches 13. This gap is filled with first conductive material 40 for forming a field plate.

Referring to FIG. 3B, the first electrically conductive material 40 is removed from an upper portion of the columnar trench 13 exposing a section of the field dielectric 19 located on the sidewall 15 of the columnar trench 13. The first electrically conductive material 40, e.g. polysilicon, is preferentially removed over the material of the field dielectric 19, e.g. SiO₂, for example by selective etching.

Referring to FIG. 3C, a portion of the exposed field dielectric 19 is removed, reducing the thickness of the field dielectric 19 on the side wall 14 of the upper portion of the columnar trench 13 and on the first major surface 12 such that field dielectric 19 has a smaller thickness on the side wall 15 in the upper portion of the columnar trench 13 and a greater thickness in the lower portion of the columnar trench 13. In this embodiment, the field dielectric 19 has two differing thicknesses on the sidewall 15, a first larger thickness in the lower section which is in contact with the remainder of the first conductive material 40 and a second smaller thickness in the upper section which is exposed from the conductive material 40.

Referring to FIG. 3D, second conductive material 41, e.g. polysilicon, is then inserted into the columnar trenches 13 to fill the trenches thus forming a structure for a field plate 18 which has a greater width in the upper part of the columnar trench 13 and a smaller width in the lower part of the columnar trench 13 and 13. One or more further dielectric materials 48 are then deposited on the first major surface 12 which cover the columnar trench 13 and the second conductive material 41 within the columnar trench 13.

Referring to FIG. 3E, a gate recess 37 is formed in the upper portion of the columnar trench 13 by removing a section of the second conductive material 41 so as to expose the field dielectric 19 of the sidewall 15 of the columnar trench 13 and form the gate recess 37 which is bounded on its outer surface by the field dielectric 19 and on its inner sidewall and remaining sidewalls by the second conductive material 41. The gate recess 37 is located laterally asymmetrically with respect to the longitudinal axis 20 of the columnar trench.

The thickness of the exposed region of the field dielectric 19 on the uppermost section 15 of the sidewall 15 of the columnar trench 30 may be further reduced as shown in FIG. 3F and may be removed entirely. Referring to FIG. 3G, an electrically insulating layer 17 is then deposited into the gate recess 37 which lines the lower surface and sidewalls of the gate recess 37 including the side wall 15 of the columnar trench 13 where it forms the gate dielectric 17 and the isolation regions 38 and 39 between the gate electrode 16 and the field-plate electrode 18 of the transistor device 10 and the side walls of the gate recess 37 that are formed by the second conductive material 41. Alternatively, the electrically insulating layer 17 is grown, for example by thermal oxidation, of the lower surface and sidewalls of the gate recess 37 including the side wall 15 of the columnar trench 13 to form the gate dielectric 17 and the isolation regions 38 and 39 that are located between the gate electrode 16 and the field-plate electrode 18 of the transistor device 10 and between the gate electrode 16 and the side walls of the gate recess 37 that are formed by the second conductive material 41.

Referring to FIG. 3H, electrically conductive material 47 is then inserted into the dielectric lined gate recess 37 to form the gate electrode 16. The gate electrode 16 is electrically insulated from the second conductive material 41 by the dielectric layer 17 which lines the side walls and lower surface of the gate recess 37 and which also forms the gate dielectric 17 on the sidewall 15 of the columnar trench 13. The second conductive material 41 forms the field plate extension 21 which is located in the upper portion of the trench 13 and laterally adjacent to the height of the gate electrode 16 and substantially parallel to the gate dielectric 17. The second conductive material 41 also forms the upper portion of the field plate 18 that is located partially under the gate electrode 16.

Referring to FIG. 3I, a planarisation process may be carried out that exposes the first major surface 12 and then one or more dielectric layers 48 may be deposited on the planarised surface which also cover the columnar trenches 13. Contacts to the gate electrode 16 and field plate 18 may be formed in a similar manner to that illustrated with reference to FIGS. 2K and 2L.

Referring to FIG. 3J, a first opening 51 is formed through the dielectric layer 48 that exposes the gate electrode 16 and may extend into the gate electrode 16. A second opening 52 is formed which exposes the second conductive material 41 and which may be sized and shaped so as to extend into the mesa 28 in the region contiguous to the side wall 15 of the columnar trench 13. Referring to FIG. 3K, conductive material 53 is inserted into the openings 51, 52 to form a first contact 22 to the gate electrode 16 and a second contact 23 to the field plate extension 21 and the mesa 28. One first contact 22 and one second contact 23 is formed in each of the columnar trenches 13. The first contacts 22 may be laterally connected together by a lateral redistribution structure 56 which is positioned on or in the dielectric layers 48 and the second contacts 23 may be electrically connected to one another by a second lateral redistribution structure 32 which extends over the upper surface of the dielectric layers 48. The first and second lateral redistribution structures 32, 56 may extend substantially parallel to one another and may be positioned on opposing sides of the columnar trenches 13.

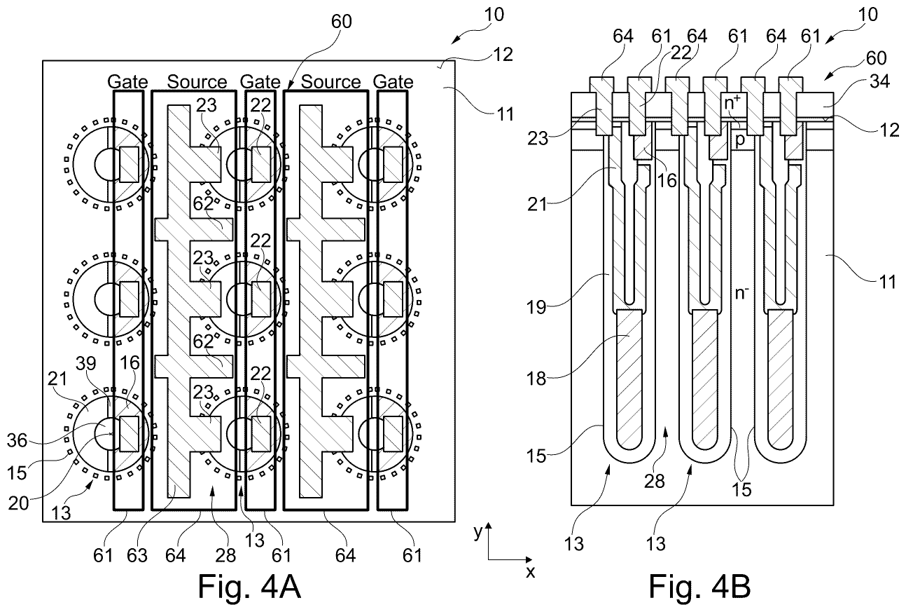

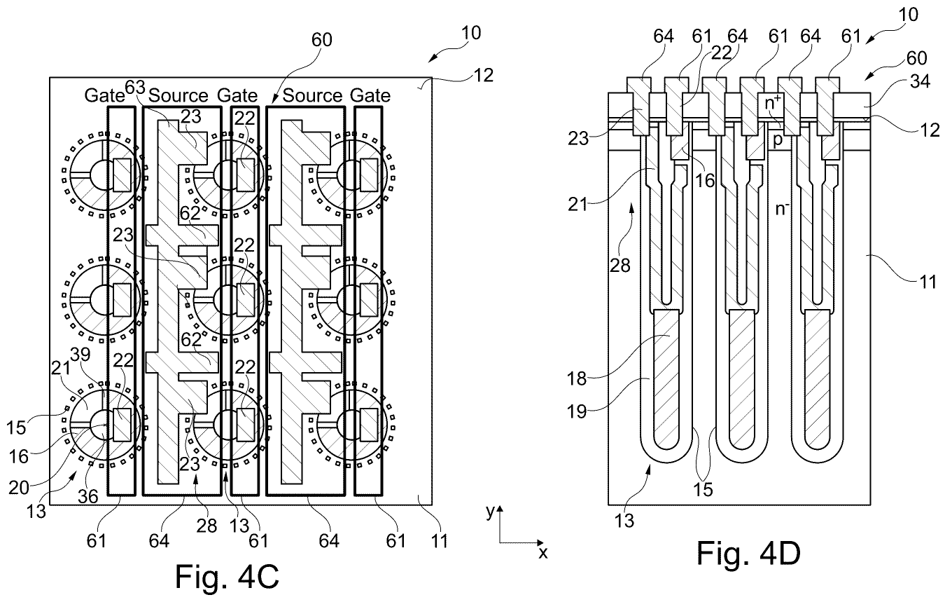

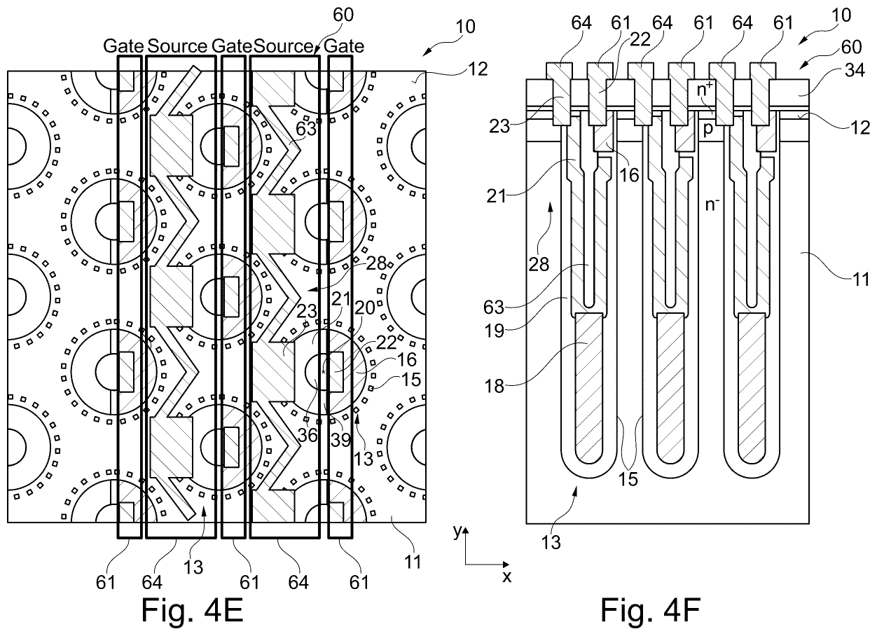

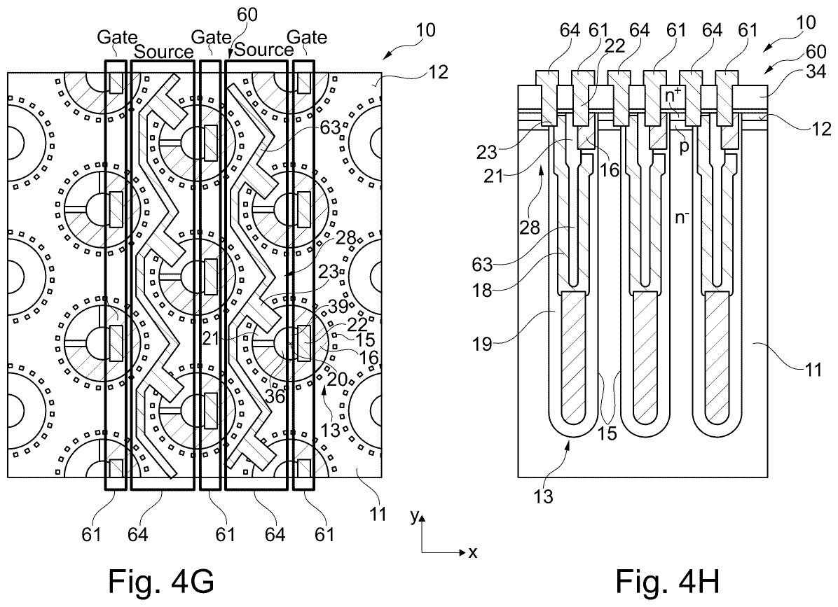

FIGS. 4A to 4H illustrate views of a metallization layer 60 according to various embodiments that may be located on the first major surface 12 of the semiconductor substrate 11 of the transistor device 10.

FIG. 4A illustrates a top view and FIG. 4B a cross-sectional view of a transistor device 10 with the metallization layer 60 according to an embodiment. The top view of FIG. 4A shows a transistor device 10 corresponding to the top view of FIG. 1C and the cross-sectional view of FIG. 4B shows the transistor device 10 corresponding to the cross-sectional view of FIG. 1D.

In this embodiment, the gate electrode 16 has an open ring type shape with an outer circumference that corresponds to slightly less than 50% of the circumference of the sidewall 15 of the columnar trench 13. The field plate extension 21 also has an open ring type structure and has an outer circumference which is slightly less than 50% of the inner circumference of the sidewall 15 of the columnar trench 13 due to the electrical insulating layer 39 arranged between the distal ends of the gate electrode 16 and field plate extension 21. One first contact 22 to the gate electrode and one second contact 23 to the field plate 18 is provided for each columnar trench 13.

The columnar trenches 13 are arranged in a square grid array or rows and columns such that the distance between the columnar trenches 13 in two perpendicular directions, the x direction and y direction using the Cartesian coordinate system, is substantially the same. The columnar trenches 13 can be considered to be arranged in a plurality of columns, each column extending in the y direction. The first contacts 22, which are electrically connected to the respective gate electrodes 16 in the columnar trenches 13 of a column, are electrically connected to one another by a strip like electrically conductive trace 61 of the metallization layer 60 that extends in the y direction. The conductive trace 61 is positioned on and electrically in contact with each of the first contacts 22 and electrically insulated from the mesas 28 located between the columnar trenches 13.

In this embodiment, the second contact 23 is sized, shaped and positioned so as to be in contact with the field plate 18 and with the mesa 28 and, in particular, with the body region 26 and source region 27 located in the mesa 28 that is contiguous to that columnar trench. Fourth contacts 62 are provided, one fourth contact 61 being positioned in the mesa 28 formed between adjacent ones of the columnar trenches 13 of the column. The fourth contacts 62 are electrically connected to the source region 27 and, optionally, also the body region 26. The fourth contact 62 may have a depth into the semiconductor substrate 11 from the first major surface 12 so as to extend into the source region 27 and the body region 26. The fourth contacts 62 may be arranged in a column with the second contacts 23, the column extending in the y direction and substantially to the column of first contacts 22 to the gate electrodes. The second and fourth contacts 23, 62 are electrically connected to one another by an electrically conductive metallization structure 63 in the first major surface 12. The electrically conductive metallization structure 63 may be strip-like and extend in the y direction and parallel to and spaced apart from the conductive trace 61 that connects the gate electrodes 16. The conductive trace 63 is electrically connected to the field plates 18 of that column and the source and body regions 26, 27 in the mesas 28.

The metallization structure 60 comprises a further conductive trace 64 which is located on the dielectric layer on the first major surface 12 and which is electrically connected to the metallization structure 63 and contacts 23, 62 that are located in the semiconductor substrate 11. A conductive trace 61 is located on the dielectric layer 34 on the first major surface 12 and electrically connects the first contacts 22 to the gate electrodes 16. The conductive trace 64 extends substantially parallel to the conductive trace 61. The conductive trace 64 may be wider than the conductive trace 61. Since the columnar trenches 13 are arranged in a plurality of columns extending substantially parallel to one another in the y direction, two conductive traces 61, 64 are provided for each column of columnar trenches 13 such that the traces 61, 64 are alternately connected to gate and source potential. The traces 61, 64 may be arranged in a layer of the metallization layer 60 which is integral and formed at the same time as the conductive material forming the contacts 22, 23, 62 and the conductive connection 63.

FIG. 4C illustrates a top view and FIG. 4D a cross-sectional view of a transistor device 10 including a metallization layer according to another embodiment. The transistor device 10 illustrated in FIGS. 4C and 4D differs from that shown in FIGS. 4A and 4B in the ratio between the area of the gate electrode 16 and the area of the field plate extension 21 at the first major surface 12 within one columnar trench 13 and in the ratio between the length of the perimeter of the gate electrode 16 and the length of the perimeter of the field plate 18 at the first major surface 12 within one columnar trench 13. In this embodiment, the gate electrode 16 has an open ring type shape with an outer circumference that corresponds to slightly less than 75% of the circumference of the sidewall 15 of the columnar trench 13. The field plate extension 21 also has an open ring type structure and has an outer circumference which is slightly less than 25% of the inner circumference of the sidewall 15 of the columnar trench 13 due to the electrical insulating layer 39 arranged between the respective distal ends of the gate electrode 16 and field plate extension 21. The open ring shape gate electrode 16 and open ring-shape field plate extension 21 together with the electrically insulating layer 39 laterally surround central rod shaped intermediate electrically insulating layer 36 within the columnar trench 13.

The position of the second contact 23 to the field plate 18 differs from that in FIG. 4A in that it is no longer aligned in the x direction with the first contact 22 to the gate electrode 16 of that columnar trench 13 but is offset in the y direction. A fourth contact 62 which is located between in the mesa 28 between two neighbouring columnar trenches 13 of a column of columnar trenches 13 that extends in the y direction is also provided. The second and fourth contacts 23, 62 are electrically connected by the conductive connection 63 as in the embodiment illustrated in FIG. 4A. The metallization layer 60 also comprises a strip-like conductive trace 64 which is located on the dielectric layer 34 on the first major surface 12. The conductive trace 64 is located on and electrically connected to the conductive connection 63 formed in the dielectric layer 34 and is electrically connected to the mesas 28 and field plates 18. The conductive trace 64 extends in the y direction substantially parallel to the conductive trace 61 that is located on the dielectric layer 34 and that is electrically connected to the gate contacts 22 of the columnar trenches 13 of a particular column. The conductive trace 64 may be integral with the conductive connection 63 and the contacts 23, 61 and the conductive trace 61 may be integral with the contacts 22. The conductive traces 61, 64 are substantially coplanar.

FIG. 4E illustrates a top view and FIG. 4F a cross-sectional view of a metallization layer 60 and transistor device 10 according to another embodiment which differs from that illustrated in FIGS. 4A and 4B in that the columnar trenches 13 are arranged in columns which are offset from one another, that is offset in the Y direction such that the columnar trenches 13 have a hexagonal arrangement.

Each of the columnar trenches 16 has an open ring-shaped gate electrode 16 and open ring-shaped field plate 18 which are substantially semicircular as in the embodiment illustrated in FIG. 4A. Similar to FIG. 4A, each of the columnar trenches 13 is associated with a first contact 22 to the gate electrode 16 and a second contact 23 to the field plate 18 in the columnar trench 13. The second contact 23 extends into the contiguous region of the mesa 28 to electrically connect the field plate to the body region 26 and source region 27. In this embodiment, the shape of the conductive trace 63, which extends between the second contacts 23, differs from that illustrated in FIG. 4A. In this embodiment, the conductive trace 63 has a zigzag structure such that it is positioned substantially equidistantly between the columnar trenches 13 within one column (in the y direction) and between the columnar trenches 13 of that and the adjoining column. The first contact 22 and second contact 23 of one columnar trench 13 of one column are aligned in the x direction but off-set in the y direction from the first contact 22 and second contact 23 of one columnar trench 13 of the adjacent column.

The metallization layer 60 further comprises a strip-like conductive trace 61 which is electrically connected to the plurality of first contacts ss and the gate electrodes 16 of the columnar trenches 13 and a conductive trace 64 which extends substantially parallel to the conductive trace 61 and which is electrically connected to the second contacts 23 and therefore to source region 26 and field plate 18.

FIG. 4G illustrates a top view and FIG. 4H a cross-sectional view of a metallization layer 60 and transistor device 10 according to another embodiment. In this embodiment, the columnar trenches 13 are arranged in off-set columns as in the top view of FIG. 4E. Each columnar trench 13 includes a gate electrode 16 and field plate 18 having the ratio of the areas and arrangement illustrated in FIG. 4C. The gate electrode 16 has an open ring type shape with an outer circumference that corresponds to slightly less than 75% of the circumference of the sidewall 15 of the columnar trench 13 and the field plate extension 21 also has an open ring type structure and has an outer circumference which is slightly less than 25% of the inner circumference of the sidewall 15 of the columnar trench 13 due to the electrical insulating layer 39 arranged between the respective distal ends of the gate electrode 16 and field plate extension 21.

In this embodiment, the second contact 23 to the field plate extension 21 are arranged offset from the first contact 22 to the gate electrode 16 of a particular columnar trench 13. The conductive trace 63, which extends between the second contacts 23, also has a zigzag or meandering structure such that it is substantially equidistant between adjacent columnar trenches 30 of one column and the columnar trenches 13 of the adjacent column of the array.

To summarise, a power MOSFET with columnar trenches is provided in which the gate electrode and the columnar field plate are located in the same columnar trench. The gate electrode and columnar field plate are electrically isolated from one another in order to reduce the gate to drain charge. The gate electrode and field-plate within the same trench may be separately contacted at the die surface, i.e. at the upper end of the columnar trench to gate and source potentials, respectively.

Pitch shrinkage and a lower RDSonA may be provided by having the gate and field-plate electrodes inside the same trench. A low gate-to-drain charge is provided by isolating the gate and field-plate electrodes with a dielectric material. A lower RdsonA may be provided by the use of a stepped field oxide.

A low voltage columnar trench MOSFET can be provided due to the possibility of reducing the pitch between the columnar trenches. The transistor device according to the present disclosure may enable low Rdson and low Qg(d) for low voltage columnar trench MOSFETs, where low voltage denotes BV s 40V. The transistor device according to the present disclosure may also be used in higher voltage classes (BV 40V), for example for FOM (Figure of Merit) optimized products with very low gate charge.

Although the present disclosure is not so limited, the following numbered examples demonstrate one or more aspects of the disclosure.

Example 1. A transistor device, comprising: a semiconductor substrate comprising a first major surface; a columnar trench arranged in the first major surface and comprising a lower surface a lower surface and a side wall, the side wall extending from the lower surface to the first major surface; a gate electrode positioned in the columnar trench and electrically insulated from the semiconductor substrate by a gate dielectric; a field plate positioned in the columnar trench under the gate electrode and electrically insulated from the gate electrode and from the semiconductor substrate by a field dielectric, wherein the gate electrode is asymmetric about a longitudinal axis of the columnar trench, and wherein the field plate comprises a field plate extension which extends from the field plate towards the first major surface and laterally adjacent to the gate electrode.

Example 2. The transistor device according to example 1, further comprising: a first contact extending from the first major surface into the columnar trench, the first contact being electrically connected to the gate electrode, and a second contact extending from the first major surface into the columnar trench, the second contact being electrically connected to the field plate, wherein the first contact and the second contact are arranged laterally adjacent to one another.

Example 3. The transistor device according to example 2, wherein the first contact and the second contact are located on opposing sides of the columnar trench.

Example 4. The transistor device according to any one of examples 1 to 3, wherein the field plate extension is laterally electrically insulated from the gate electrode by an intermediate dielectric.

Example 5. The transistor device according to example 4, wherein the intermediate dielectric is located centrally in the columnar trench and extends from the first major surface to the field plate.

Example 6. The transistor device according to any one of examples 1 to 5, wherein the field plate extension and the gate electrode each comprise an arc.

Example 7. The transistor device according to any one of examples 1 to 7, wherein the gate electrode is provided by a single electrically conductive portion having an open ring-shape with a gap located between two distal ends of the open ring shape.

Example 8. The transistor device according to example 6, wherein the field plate extension is located in the gap of the gate electrode.

Example 9. The transistor device according to any one of examples 1 to 8, wherein a first thickness of the field dielectric at a first distance from the lower surface is smaller than a second thickness of the field dielectric at a second distance from the lower surface, wherein the first distance is greater than the second distance and wherein a first perimeter of the columnar field plate at the first distance is greater than a second perimeter of the columnar field plate at the second distance.

Example 10. The transistor device according to example 9, wherein the side face of the field plate comprises a step such that an upper portion of the field plate has a width that is greater than a width of a lower portion of the field plate and such that the field dielectric has a first thickness t₁ in a first region of the side wall of the columnar trench and a second thickness t2 in a second region of the side wall of the columnar trench, wherein t₁≤1.15 t₂ or t₁≤1.2 t₂ or t1≤1.5 t₂.

Example 11. The transistor device according to any one of examples 7 to 10, wherein the second contact that is positioned at least partially in the gap.

Example 12. The transistor device according to any one of examples 1 to 11, wherein the field plate extension extends to the first major surface.

Example 13. The transistor device according to any one of examples 1 to 12, wherein: the columnar trench has a maximum area at in a plane that is parallel to the first major surface and the gate electrode is sized and shaped so as to have a maximum area a_{g} in the plane that is parallel to the first major surface and such that 10%≤(a_{g}/aₜ)*100≤90% or 20%≤(a_{g}/aₜ)*100≤80%, 25%≤(a_{g}/aₜ)*100≤75%; and/or the field plate extension is sized and shaped so as to have a maximum area aₑ in the plane that is parallel to the first major surface and such that 10%≤(aₑ/aₜ)*100≤90% or 20%≤(aₑ/aₜ)*100≤80%, 25%≤(aₑ/aₜ)*100≤75%; and/or a ratio of aₑ/a_{g} lies within the range of 1/9 to 9/1, and/or wherein the columnar trench has a circumference length Aₜ in a plane that is parallel to the first major surface and the gate electrode is sized and shaped so as to have a maximum circumferential length A_{g} in the plane that is parallel to the first major surface and such that 10%≤(A_{g}/Aₜ)*100≤90% or 20%≤(A_{g}/Aₜ)*100≤80%, 25%≤(A_{g}/Aₜ)*100≤75%; and/or the field plate extension is sized and shaped so as to have a maximum circumferential length Aₑ in the plane that is parallel to the first major surface and such that 10%≤(Aₑ/Aₜ)*100≤90% or 20%≤(Aₑ/Aₜ)*100≤80%, 25%≤(Aₑ/Aₜ)*100≤75%; and/or a ratio of Aₑ/A_{g} lies within the range of 1/9 to 9/1.

Example 14. The transistor device according to any one of examples 1 to 13, wherein the field plate comprises a lower portion and an upper portion that are located under the gate electrode, wherein the lower portion has a smaller area than the upper portion.

Example 15. The transistor device according to any one of examples 1 to 14, wherein the semiconductor substrate comprises a drain region of a first conductivity type formed at the second surface, a drift region of the first conductivity formed on the drain region, a body region of a second conductivity type that opposes the first conductivity type formed on the drift region and a source region of a first conductivity type formed on and/or in the body region.

Example 16. The transistor device of any one of examples 1 to 15, wherein the transistor device comprises a plurality of columnar trenches arranged in an array, and further comprises a metallization layer located on the first major surface, wherein the metallization structure comprises: a first metallization structure extending between the first contacts of the columnar trenches, and a second metallization structure extending between the second contacts of the columnar trenches, wherein the first metallization structure and the second metallization structure extend substantially parallel to one another.

Example 17. The transistor device according to example 16, wherein the second metallization structure electrically connects the field plates to the source region.

Example 18. The transistor device according to example 16 or example 17, wherein the second contact extends between and is in contact with the field plate and the source region.

Example 19. A method of forming a gate electrode and a field plate in a columnar trench, the method comprising: providing a semiconductor substrate having a first major surface and a columnar trench comprising a lower surface and a side wall that extends from the lower surface to the first major surface, wherein the side wall and lower surface are lined with a field dielectric and the columnar trench is filled with first conductive material; partially removing the field dielectric and conductive material from the columnar trench and forming a gate recess that is located in the columnar trench asymmetrically with respect to a longitudinal axis of the columnar trench; forming a dielectric on walls of the recess; inserting second conductive material into the gate recess to form a gate electrode, wherein the first conductive material extends to the first major surface laterally adjacent the gate electrode and form the field plate.

Example 20. The method according to example 19, wherein the partially removing the dielectric and conductive material from the columnar trench comprises: exposing the field dielectric at the top of the columnar trench, forming a conductive layer on the exposed field dielectric and on the conductive material in the lower surface of the trench, wherein the conductive layer extends to the first major surface and surrounds a central gap; forming an intermediate electrically insulating layer in the central gap; and partially removing the conductive layer and exposing the intermediate electrically insulating layer and the field dielectric on the side wall to form the gate recess.

Example 21. The method according to example 20, the method further comprising: applying a mask to the first major surface that covers a first portion of the conductive layer and exposes a second portion of the conductive layer and partially covers the intermediate electrically insulating layer within the columnar trench; removing the exposed second portion of the conductive layer and forming the gate recess; and removing the mask.

Example 22. The method according to any one of examples 19 to 21, the method further comprising: applying an electrically insulating layer to the first major surface that covers the trenches, forming a first opening that exposes the gate electrode; forming a second opening that exposes the field plate electrode; and inserting conductive material into the first and second opening to form a first contact to the gate electrode and a second contact to the field plate.

Example 23. The method according to example 22, wherein the second opening further exposes the source region and the body region and the second contact is further connected to the source region and the body region.

Example 24. The method according to example 22, further comprising forming a third opening that exposes the body region and the source region and inserting the conductive material into the third opening to form a third contact to the source region and the body region that is separate from the second contact to the field plate.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a semiconductor substrate comprising a first major surface;
a columnar trench arranged in the first major surface and comprising a lower surface and a side wall, the side wall extending from the lower surface to the first major surface;
a gate electrode positioned in the columnar trench and electrically insulated from the semiconductor substrate by a gate dielectric; and
a field plate positioned in the columnar trench under the gate electrode and electrically insulated from the gate electrode and from the semiconductor substrate by a field dielectric,
wherein the gate electrode is asymmetric about a longitudinal axis of the columnar trench,
wherein the field plate comprises a field plate extension which extends from the field plate towards the first major surface and laterally adjacent to the gate electrode.

2. The transistor device of claim 1, further comprising:
a first contact extending from the first major surface into the columnar trench, the first contact being electrically connected to the gate electrode; and
a second contact extending from the first major surface into the columnar trench, the second contact being electrically connected to the field plate,
wherein the first contact and the second contact are arranged laterally adjacent to one another.

3. The transistor device of claim 2, wherein the first contact and the second contact are located on opposing sides of the columnar trench.

4. The transistor device of claim 1, wherein the field plate extension is laterally electrically insulated from the gate electrode by an intermediate dielectric.

5. The transistor device of claim 4, wherein the intermediate dielectric is located centrally in the columnar trench and extends from the first major surface to the field plate.

6. The transistor device of claim 1, wherein the gate electrode is provided by a single electrically conductive portion having an open ring-shape with a gap located between two distal ends of the open ring shape.

7. The transistor device of claim 6, wherein the field plate extension is located in the gap of the gate electrode.

8. The transistor device of claim 6, further comprising:
a first contact extending from the first major surface into the columnar trench, the first contact being electrically connected to the gate electrode; and
a second contact extending from the first major surface into the columnar trench, the second contact being electrically connected to the field plate,
wherein the first contact and the second contact are arranged laterally adjacent to one another, and
wherein the second contact is positioned at least partially in the gap.

9. The transistor device of claim 1, wherein the field plate extension extends to the first major surface.

10. The transistor device of claim 1, wherein a first thickness of the field dielectric at a first distance from the lower surface is smaller than a second thickness of the field dielectric at a second distance from the lower surface, wherein the first distance is greater than the second distance, and wherein a first perimeter of the columnar field plate at the first distance is greater than a second perimeter of the columnar field plate at the second distance.

11. The transistor device of claim 1, wherein a side face of the field plate comprises a step such that an upper portion of the field plate has a width that is greater than a width of a lower portion of the field plate and such that the field dielectric has a first thickness t₁ in a first region of the side wall of the columnar trench and a second thickness t2 in a second region of the side wall of the columnar trench, wherein t₁≤1.15 t₂ or t₁≤1.2 t₂ or t1≤1.5 t₂.

12. The transistor device of claim 1, wherein:
the columnar trench has a maximum circumference Aₜ in a plane that is parallel to the first major surface and the gate electrode is sized and shaped so as to have a maximum circumferential length A_{g} in the plane that is parallel to the first major surface and such that 10%≤(A_{g}/Aₜ)*100≤90% or 20%≤(A_{g}/Aₜ)*100≤80%, 25%≤(A_{g}/Aₜ)*100≤75%; and/or
the field plate extension is sized and shaped so as to have a maximum circumferential length Aₑ in the plane that is parallel to the first major surface and such that 10%≤(Aₑ/Aₜ)*100≤90% or 20%≤(Aₑ/Aₜ)*100≤80%, 25%≤(Aₑ/Aₜ)*100≤75%; and/or
a ratio of Aₑ/A_{g} lies within the range of 1/9 to 9/1.

13. The transistor device of claim 1, wherein the transistor device comprises a plurality of columnar trenches arranged in an array, and a metallization layer located on the first major surface, wherein the metallization layer comprises:
a first metallization structure extending between the first contacts of the columnar trenches; and
a second metallization structure extending between the second contacts of the columnar trenches,
wherein the first metallization structure and the second metallization structure extend substantially parallel to one another.

14. The transistor device of claim 13, wherein the second metallization structure electrically connects the field plates to the source region.

15. A method of forming a gate electrode and a field plate in a columnar trench, the method comprising:
providing a semiconductor substrate having a first major surface and a columnar trench comprising a lower surface and a side wall that extends from the lower surface to the first major surface, wherein the side wall and lower surface are lined with a field dielectric and the columnar trench is filled with first conductive material;
partially removing the field dielectric and partially removing the first conductive material from the columnar trench and forming a gate recess that is located in the columnar trench asymmetrically with respect to a longitudinal axis of the columnar trench;
forming a dielectric on walls of the recess; and
inserting second conductive material into the gate recess to form a gate electrode,
wherein the first conductive material extends to the first major surface laterally adjacent the gate electrode and forms the field plate.

16. The method of claim 15, wherein the partially removing the field dielectric and conductive material from the columnar trench comprises:
recessing the first conductive material at a top of the columnar trench;
exposing the field dielectric at the top of the columnar trench;
forming a conductive layer on the exposed field dielectric and on the conductive material in the lower surface of the trench, wherein the conductive layer extends to the first major surface and surrounds a central gap;
forming an intermediate electrically insulating layer in the central gap; and
partially removing the conductive layer and exposing the intermediate electrically insulating layer and the field dielectric on the side wall to form the gate recess.

17. The method of claim 16, further comprising:
applying a mask to the first major surface that covers a first portion of the conductive layer and exposes a second portion of the conductive layer and partially covers the intermediate electrically insulating layer within the columnar trench;
removing the exposed second portion of the conductive layer and forming the gate recess; and
removing the mask.

18. The method of claim 15, further comprising:
applying an electrically insulating layer to the first major surface that covers the trenches;
forming a first opening that exposes the gate electrode;
forming a second opening that exposes the field plate; and
inserting conductive material into the first opening and the second opening to form a first contact to the gate electrode and a second contact to the field plate.

19. The method of claim 18, wherein the second opening further exposes the source region and the body region and the second contact is further connected to the source region and the body region.

20. The method of claim 18, further comprising:
forming a third opening that exposes the body region and the source region; and
inserting the conductive material into the third opening to form a third contact to the source region and the body region that is separate from the second contact to the field plate.
